(19) United States
(12) Patent Application Publication
(10) Pub. No.: US 2026/0361322 A1
(43) Pub. Date: Nov. 12, 2026

(54) METHOD AND ELECTRONIC DEVICE FOR COMMUNICATION WITH POLAR CODED EXTENSION

(71) Applicant: POSTECH RESEARCH AND BUSINESS DEVELOPMENT FOUNDATION, Pohang-si (KR)

(72) Inventors: Nam Yoon LEE, Pohang-si (KR); Geon CHOI, Pohang-si (KR)

(73) Assignee: POSTECH RESEARCH AND BUSINESS DEVELOPMENT FOUNDATION, Pohang-si (KR)

(21) Appl. No.: 19/304,505

(22) Filed: Aug. 19, 2025

(30) Foreign Application Priority Data
May 8, 2025 (KR) 10-2025-0059996
Jun. 17, 2025 (KR) 10-2025-0079796

(51) Int. Cl. H03M 13/13; H04L 1/00

(52) U.S. Cl. CPC H03M 13/13; H04L 1/0041; H04L 1/0057; H04L 1/0013

(57) ABSTRACT

Provided are a method and an electronic device, for communication using polar code extension. The method for communication includes generating rate-matching deep polar codes by combining pre-transformed codewords with polar-transformed codewords. The method for communication includes decoding an extended portion and then decoding a polar codeword by using soft information of the extended portion.

### CROSS-REFERENCE TO RELATED APPLICATION

This application is based on and claims priority under 35 U.S.C. § 119 to Korean Patent Application No. 10-2025-0059996, filed on May 8, 2025, and Korean Patent Application No. 10-2025-0079796, filed on Jun. 17, 2025, in the Korean Intellectual Property Office, the disclosures of which are incorporated by reference herein in their entirety.

### BACKGROUND

### 1. Field

One or more embodiments relate to communication, and more particularly, to a method and an electronic device for communication using polar coded extension.

This research has been conducted with support from the Samsung Future Technology Promotion Project (Project Number: SRFC-IT2302-04).

### 2. Description of the Related Art

Polar codes are one of the channel codes which achieve channel capacity within the range of an infinite block length (IBL). Polar codes are restricted to block lengths of powers of 2.

Rate-matching techniques are needed to support arbitrary code lengths and code rates. Puncturing approaches such as quasi-uniform puncturing (QUP) remove specific bits from a longer mother code. Meanwhile, shortening approaches fix specific bits to known values before transmission. Both the approaches use longer mother codes, and thus decoding complexity increases in many cases.

### SUMMARY

One or more embodiments include rate-matching deep polar codes whose code length is not limited to a power of 2. One or more embodiments include rate-matching deep polar codes with improved reliability.

Additional aspects will be set forth in part in the description which follows and, in part, will be apparent from the description, or may be learned by practice of the presented embodiments of the disclosure.

According to one or more embodiments, a method for communication includes applying a pre-transformation to a second input bit sequence to obtain second coded bits, applying a polar transformation to a first input bit sequence including the second coded bits, to obtain first coded bits, and combining the first coded bits with the second coded bits.

The combining may include combining the first coded bits with the second coded bits such that the combined coded bits have a code length that is not a power of 2.

The applying of the polar transformation to the first input bit sequence may include generating the first input bit sequence including one or more first information bits, one or more first frozen bits, and the second coded bits.

The generating of the first input bit sequence may include assigning the one or more first information bits, the second coded bits, and the one or more first frozen bits to the first input bit sequence in the order from highest to lowest channel reliability.

The applying of the pre-transformation to the second input bit sequence may include generating the second input bit sequence including one or more second information bits and one or more second frozen bits.

The method for communication may further include applying a pre-transformation to a third input bit sequence to obtain third coded bits. The applying of the polar transformation to the first input bit sequence may include applying a polar transformation to the first input bit sequence including the second coded bits and the third coded bits, to obtain the first coded bits. The combining may include combining the first coded bits, the second coded bits, and the third coded bits.

The method for communication may further include applying a pre-transformation to a third input bit sequence in order to obtain third coded bits. The applying of the pre-transformation to the second input bit sequence may include applying a pre-transformation to the second input bit sequence including the third coded bits, to obtain the second coded bits. The combining may include combining the first coded bits, the second coded bits, and the third coded bits.

The applying of the pre-transformation to the second input bit sequence may include applying, to the second input bit sequence, a pre-transformation matrix that is a transpose of a polar transformation matrix, and the applying of the pre-transformation to the third input bit sequence may include applying, to the third input bit sequence, a pre-transformation matrix that is a polar transformation matrix.

A code rate of the combined coded bits may be a ratio of a sum of a length of an information bit of the first coded bits and a length of an information bit of the second coded bits to a sum of a code length of the first coded bits and a code length of the second coded bits.

The applying of the pre-transformation to the second input bit sequence may include applying, to the second input bit sequence, a pre-transformation matrix that is a transpose of a polar transformation matrix.

According to one or more embodiments, an electronic device for communication includes a memory storing instructions, and a processor configured to execute the instructions, wherein the processor is configured to execute the instructions to apply a pre-transformation to a second input bit sequence to obtain second coded bits, apply a polar transformation to a first input bit sequence including the second coded bits, to obtain first coded bits, and combine the first coded bits with the second coded bits.

According to one or more embodiments, a method for communication includes receiving a combined received signal of a first received signal and a second received signal, wherein the first received signal corresponds to first coded bits, the second received signal corresponds to second coded bits, and the first coded bits are generated by applying a polar transformation to an input bit sequence including the second coded bits, performing a second decoding operation on the second received signal to obtain second decoded bits and second reliability information for the second coded bits, and, to obtain first decoded bits, performing a first decoding operation on the first received signal, based on first reliability information based on the first received signal or the second reliability information.

The performing of the first decoding operation on the first received signal may include performing a first decoding operation with respect to elements of the first input bit sequence indexed by a predetermined index set, based on the first reliability information and the second reliability information, and performing a first decoding operation with respect to elements of the first input bit sequence not indexed by the predetermined index set, based on the first reliability information.

The second coded bits may be generated by applying a pre-transformation to a second input bit sequence including one or more information bits and one or more frozen bits, and the predetermined index set may be a set that includes, as elements, indices of coded bits corresponding to the one or more information bits among the second coded bits in the first input bit sequence.

The performing of the first decoding operation, based on the first reliability information and the second reliability information may include performing successive cancellation list (SCL) decoding via a path metric update based on the first reliability information and the second reliability information. The performing of the first decoding operation, based on the first reliability information, may include performing SCL decoding via a path metric update based on the first reliability information.

The second reliability information may include log-likelihood ratio (LLR) values for the second coded bits.

The first reliability information may include LLR values of SCL decoding based on the first received signal.

The combined received signal may correspond to combined coded bits of the first coded bits and the second coded bits, the first coded bits may be generated by applying a polar transformation to a first input bit sequence including one or more information bits, one or more frozen bits, and the second coded bits, and the second coded bits may be generated by applying a pre-transformation to a second input bit sequence including one or more information bits and one or more frozen bits.

The receiving of the combined received signal may include receiving a combined received signal of the first received signal, the second received signal, and a third received signal, wherein the third received signal corresponds to third coded bits, and the first coded bits are generated by applying a polar transformation to an input bit sequence including the second coded bits and the third coded bits. The method for communication may further include performing a second decoding operation on the third received signal to obtain third decoded bits and third reliability information for the third coded bits. The performing of the first decoding operation may further include performing a first decoding operation on the first received signal, based on first reliability information based on the first received signal, the second reliability information, or the third reliability information.

The receiving of the combined received signal may include receiving a combined received signal of the first received signal, the second received signal, and a third received signal, wherein the third received signal corresponds to third coded bits, and the second coded bits are generated by applying a pre-transformation to an input bit sequence including the third coded bits. The method for communication may further include performing a third decoding operation on the third received signal to obtain third decoded bits and third reliability information for the third coded bits, and the performing of the second decoding operation may further include performing the second decoding operation on the second received signal, based on the third reliability information.

### BRIEF DESCRIPTION OF THE DRAWINGS

The above and other aspects, features, and advantages of certain embodiments of the inventive concept will be more apparent from the following description taken in conjunction with the accompanying drawings, in which:

FIG. 1 is a diagram illustrating a channel coding system according to an embodiment;

FIGS. 2 through 4 are block diagrams of electronic devices according to embodiments;

FIG. 5 is a view for describing encoding of single-layer extended deep polar codes according to an embodiment;

FIGS. 6 and 7 are views for describing encoding of multi-layer extended deep polar codes according to embodiments;

FIG. 8 is a view for describing decoding of single-layer extended deep polar codes according to an embodiment;

FIGS. 9 and 10 are views for describing decoding of multi-layer extended deep polar codes according to embodiments;

FIG. 11 is a view illustrating an example of extended deep polar codes according to an embodiment;

FIG. 12 is a graph for explaining an improvement in reliability of extended deep polar codes according to an embodiment;

FIGS. 13 through 15 are flowcharts of encoding operations according to embodiments; and

FIGS. 16 through 18 are flowcharts of decoding operations according to embodiments.

### DETAILED DESCRIPTION

The advantages and features of disclosed embodiments and methods of achieving the advantages and features will become apparent with reference to embodiments described below with reference to the accompanying drawings. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

It will be understood that each block of a flowchart may be implemented by computer program instructions. These computer program instructions may be provided to a processor of a general-purpose computer, special purpose computer, or other programmable data processing equipment, such that the instructions, which are executed via the processor of the computer or other programmable data processing equipment, generate means for performing functions specified in the block(s). These computer program instructions may also be stored in a computer-usable or computer-readable memory that may direct a computer or other programmable data processing equipment to function in a particular manner, such that the instructions stored in the computer-usable or computer-readable memory produce a manufactured article including instruction means that perform the functions specified in the block(s). The computer program instructions may also be loaded onto a computer or other programmable data processing equipment to cause a series of operational steps to be performed on the computer or other programmable data processing equipment to produce a computer-executable process such that the instructions that are executed on the computer or other programmable data processing equipment provide steps for implementing the functions specified in the block(s). In addition, each block may represent a module, segment, or portion of code, which includes one or more executable instructions for implementing specified logical function(s).

Terms used herein will be described briefly, and disclosed embodiments will be described in detail.

Although general terms widely used at present were selected for describing the disclosure in consideration of the functions thereof, terms used herein may vary according to intentions of one of ordinary skill in the art, case precedents, the advent of new technologies, and the like. Terms arbitrarily selected by the applicant of the disclosure may also be used in a specific case. In this case, their meanings need to be given in the detailed description of the disclosure. Hence, the terms must be defined based on their meanings and the contents of the entire specification, not by simply stating the terms.

In the disclosure, for convenience of explanation, a lower suffix notation indicating vector indexing is used. For example, when a vector u=[1,3,2,4,5] and a set A={2,4} for indexing are given, u_{A}=[u₂,u₄]=[3,4] in the vector indexing using the lower suffix notation. For example, when a vector u₁=[1,3,2,4,5] and a set A={1,2} for indexing are given, u_{1,A}=[u_{1,1},u_{1,2}]=[1,3] in the vector indexing using the lower suffix notation.

In the disclosure, for brevity, a permutation operation may be omitted. For example, the permutation operation may be omitted as in Equation 10.

In this disclosure, {0,1} k is a set whose elements are binary numbers from 0 to 2^{k}−1. For example, {0,1}²={00, 01, 10, 11}.

Throughout the present disclosure, the expression “at least one of a, b or c” indicates only a, only b, only c, both a and b, both a and c, both b and c, all of a, b, and c, or variations thereof.

An expression used in the singular encompasses the expression of the plural, unless the context clearly indicates singular forms.

The terms “comprises” and/or “comprising” or “includes” and/or “including” when used in this specification, specify the presence of stated elements, but do not preclude the presence or addition of one or more other elements.

Also, the term “unit” used herein means a software component, or a hardware component, and performs a certain function. However, the term “unit” is not limited to software or hardware. The term “unit” may be configured to be included in an addressable storage medium or to reproduce one or more processors. Thus, for example, the term “unit” may refer to components such as software components, object-oriented software components, class components, and task components, and may include processes, functions, attributes, procedures, subroutines, segments of program code, drivers, firmware, micro codes, circuits, data, a database, data structures, tables, arrays, or variables. Functions provided by the components and “units” may be associated with the smaller number of components and “units”, or may be divided into additional components and “units”.

The term “processor” should be widely interpreted as including a general-purpose processor, a central processing unit (CPU), a microprocessor, a digital signal processor (DSP), a controller, a microcontroller, a state machine, etc. In some environments, the “processor” may also refer to an application specific integrated circuit (ASIC), a programmable logic device (PLD), a field-programmable gate array (FPGA), etc. The term “processor” may also refer to a combination of processing devices, such as a combination of a DSP and a microprocessor, a combination of a plurality of microprocessors, a combination of one or more microprocessors combined with a DSP core, or a combination of other such arbitrary components.

The term “memory” should be widely interpreted as including an arbitrary electronic component capable of storing electronic information. The term memory may refer to various types of processor-readable media, such as a random-access memory (RAM), a read-only memory (ROM), a nonvolatile RAM (NVRAM), a programmable ROM (PROM), an erasable-PROM (EPROM), an electrically EPROM (EEPROM), a flash memory, a magnetic or optical data storage, registers, etc. When a processor is to read and/or record information from and/or in the memory, the memory may be referred to as being in an electronic communication state with the processor. The memory integrated into the processor may be in an electronic communication state with the processor.

Various embodiments of the disclosure will be described below with reference to the accompanying drawings.

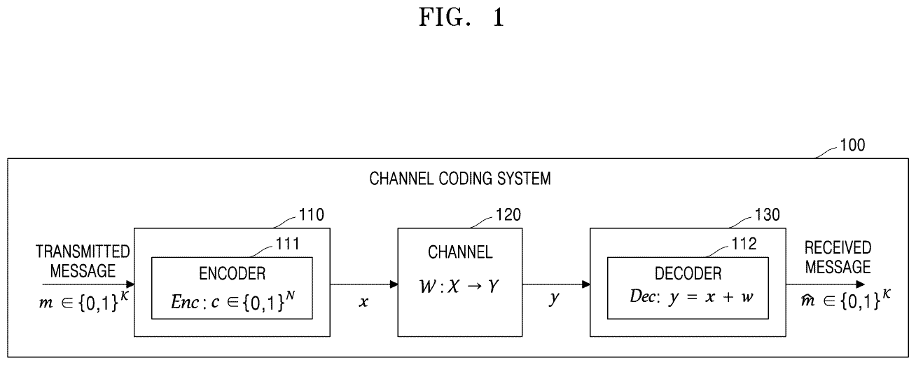

FIG. 1 is a schematic diagram illustrating a channel coding system 100 according to an embodiment.

It is important to configure the channel coding system 100 such that a transmitted message m and a received message \hat{m} are the same as each other. To this end, a transmitter 110 may generate a codeword c by performing channel encoding for more reliably transmitting the transmitted message m, and may transmit a modulated symbol vector x through a channel 120 W:X→Y. Also, a receiver 130 may receive a codeword y including noise and perform channel decoding to reconstruct the received message \hat{m}.

An encoder 111 may encode the transmitted message m of K bits to generate the codeword c of N bits. The transmitted message m may be expressed by Equation 1 below.

m=[m₀,m₁, . . . ,m_{K-1}]∈{0,1}^{K} [Equation 1]
where, as for k∈K, mₖ is an independent and uniformly distributed random variable with respect to {0,1}. {0,1}^{K} is a set having binary numbers from 0 to 2^{K}−1 as elements. For example, {0,1}²={00, 01, 10, 11}.

The codeword c may be expressed by Equation 2 below.

c=[c₀,c₁, . . . ,c_{N-1}] [Equation 2]

A code rate is defined as a ratio of transmitted information bits to a code block length. For example, a code rate of the transmitted message m and the codeword c is K/N.

The encoder 111 may generate the codeword c by using polar transformation. A polar transformation matrix G of a size N=2ⁿ may be obtained via F_{N}, which is n-th Kronecker power of a binary kernel matrix F₂. The binary kernel matrix F₂ and the n-th Kronecker power F_{N} of the binary kernel matrix F₂ may be respectively expressed by Equations 3 and 4 below.

$${F}_{2} = [ \begin{matrix}1 & 0 \\ 1 & 1\end{matrix} ] \qquad [ Equation 3 ]$$

$${F}_{N} = {F}_{2}^{⊗ n} \qquad [ Equation 4 ]$$

The encoder 111 may generate the codeword c by applying polar transformation to an input vector u including the transmitted message m and frozen bits. An information index set I refers to a set whose elements are locations of information bits (i.e., bits of a transmitted message) in the input vector u. That is, u_{I}=m. A frozen index set F refers to a set whose elements are locations of frozen bits in the input vector u. That is, u_{F}=0.

The encoder 111 may modulate the codeword c by using Binary Phase Shift Keying (BPSK). The modulation of the encoder 111 may be expressed as Equation 5 below.

x=1−2c [Equation 5]

The modulated codeword x may pass the channel 120. The channel 120 may be an additive white Gaussian noise (AWGN) channel. A signal y (that is, a codeword having passed a channel) received from the channel 120 may be expressed by Equation 6 below.

y=x+w [Equation 6]
where additive noise w is a zero-mean Gaussian random variable of mean 0 and variance σ².

A decoder 112 may decode the codeword y to generate the received message \hat{m} of K bits. The decoder 112 may be designed to minimize a block error rate (BLER). The BLER may denote a ratio of the number of error blocks to the total number of transmitted blocks.

With respect to the channel 120 W:X→Y, a symmetric capacity may be used as a channel parameter related to the BLER. The BLER is related to a channel reliability. As the channel reliability increases, the BLER may decrease. In contrast, as the channel reliability decreases, the BLER may increase. The symmetric capacity is a parameter related to a maximum transmission amount which may be transmitted with a high reliability in a channel. As the symmetric capacity increases, the BLER may decrease to increase the channel reliability. Accordingly, the information index set I may be set to index channels with high reliability, i.e., channels with high symmetric capacity.

When the channel 120 is a Binary-input Discrete Memoryless Channel (B-DMC), a channel capacity I (W) may be expressed by Equation 7 below.

$$I ( W ) \dot{=} {\sum }_{y ∈ Y} {\sum }_{x ∈ X} \frac{1}{2} W ( y \vert x ) {log}_{2} \frac{W ( y \vert x )}{\frac{1}{2} W ( y \vert 0 ) + \frac{1}{2} W ( y \vert 1 )} \qquad [ Equation 7 ]$$

where X represents a binary alphabet, and Y represents an arbitrary alphabet. W(y|x) represents a transition probability of a channel W for an input x and an output y.

The decoder 112 may perform successive cancellation list (SCL) decoding. To mitigate error propagation, the decoder 112 may maintain a maximum of L decoding candidates. The decoder 112 may calculate a path metric representing path reliability, and may select L decoding candidates having smallest path metrics.

In SCL decoding, a path metric PMᵢ[l] of an l-th decoding candidate may be expressed by Equation 8 below.

PMᵢ[l]=PMᵢ₋₁[l]+log(1+ [symbol] ) [Equation 8]
where PMᵢ₋₁ [l] represents an accumulated path metric of up to an (i−1)th bit of an l-th path, L_{n,i} represents an LLR of an i-th bit of an n-th depth of SCL decoding, and ûᵢ[l] represents an estimate of an i-th bit of the l-th path.

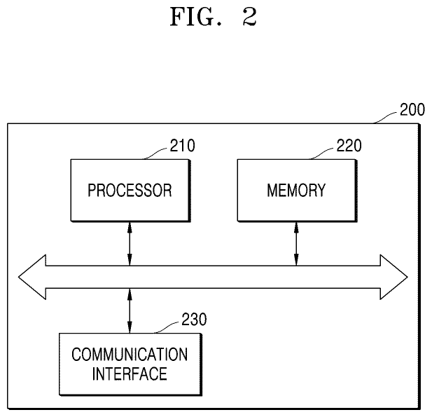

FIG. 2 is a block diagram of an electronic device 200 according to an embodiment.

The electronic device 200 may include a processor 210, a memory 220, and a communication interface 230. The memory 220 and the communication interface 230 are capable of communicating with the processor 210.

The electronic device 200 may be a transmitter or receiver of communication.

The processor 210 may control overall operations of the electronic device 200. For example, the processor 210 may control overall operations of the electronic device 200 for performing communication, by executing one or more instructions of a program stored in the memory 220. The processor 210 may be included as one or more.

For example, the processor 210 may include, but is not limited to, at least one of a CPU, a microprocessor, a graphics processing unit (GPU), application specific integrated circuits (ASICs), a digital signal processors (DSP), a digital signal processing devices (DSPD), a programmable logic devices (PLD), a field programmable gate array (FPGA), an application processor, or a neural processing unit (NPU).

Instructions, a data structure, and program code readable by the processor 210 may be stored in the memory 220. Operations performed by the processor 210 may be implemented by executing the instructions or codes of a program stored in the memory 220.

For example, the memory 220 may include, but is not limited to, non-volatile memory including at least one of a Read-Only Memory (ROM), an Electrically Erasable Programmable Read-Only Memory (EEPROM), a Programmable Read-Only Memory (PROM), a magnetic memory, a magnetic disk, or an optical disk, and volatile memory such as a Random Access Memory (RAM) or a Static Random Access Memory (SRAM). For example, the memory 220 may include, but is not limited to, a flash memory type, a hard disk type, a multimedia card micro type, or a card type memory (e.g., an Secure Digital (SD) card or an XD-picture card).

The communication interface 230 may perform data communication with other electronic devices under a control by the processor 210.

For example, the communication interface 230 may include a communication circuit capable of performing data communication with the electronic device 200 or the other electronic devices by using at least one of data communication methods including a wired LAN, a wireless LAN, Wi-Fi, Bluetooth, Zigbee, Wi-Fi Direct (WFD), infrared communication (IrDA), Bluetooth Low Energy (BLE), near field communication (NFC), wireless broadband Internet (Wibro), world interoperability for Microwave Access (WiMAX), a shared wireless access protocol (SWAP), wireless gigabit alliances (WiGig), and radio frequency (RF) communication. However, embodiments are not limited thereto.

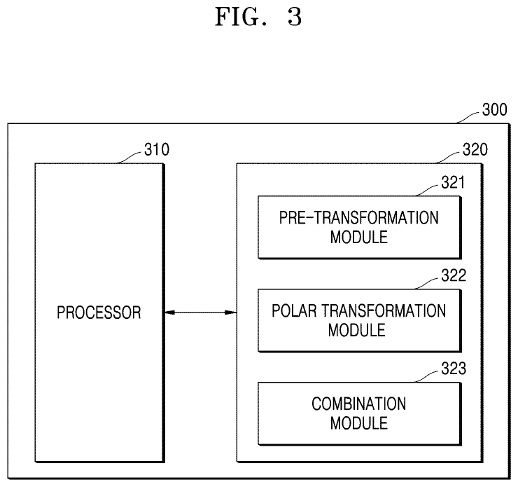

FIG. 3 is a block diagram of an electronic device 300 according to an embodiment.

In description of FIG. 3, any content that overlaps with that described above with reference to FIG. 2 is omitted for brevity.

The electronic device 300 may include a processor 310 and a memory 320. The electronic device 300 may be a transmitter.

The memory 320 may store one or more instructions and/or programs for causing the electronic device 300 to perform encoding. According to an embodiment, the memory 320 may store instructions and/or programs for implementing functions of a pre-transformation module 321, a polar transformation module 322, and a combination module 323.

The functions of the pre-transformation module 321, the polar transformation module 322, and the combination module 323 may be executed by the processor 310. Accordingly, operations that are described in the disclosure to be performed by the pre-transformation module 321, the polar transformation module 322, and the combination module 323 may be executed by the processor 310 in practice.

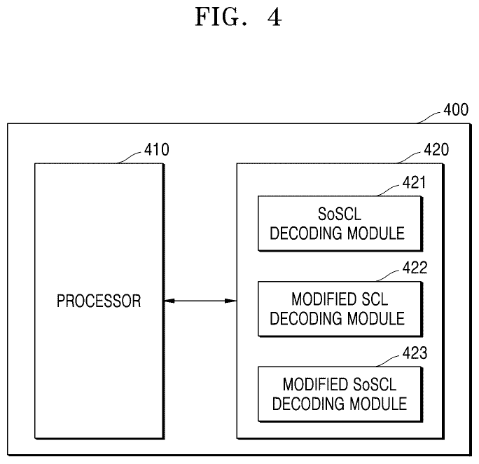

FIG. 4 is a block diagram of an electronic device 400 according to an embodiment.

In description of FIG. 4, any content that overlaps with that described above with reference to FIG. 2 is omitted for brevity.

The electronic device 400 may include a processor 410 and a memory 420. The electronic device 400 may be a receiver.

The memory 420 may store one or more instructions and/or programs for causing the electronic device 400 to perform decoding. According to an embodiment, the memory 420 may store instructions and/or programs for implementing functions of a soft-output successive cancellation list (SoSCL) decoding module 421 and a modified SCL decoding module 422. The memory 420 may further store instructions and/or programs for implementing functions of a modified SoSCL decoding module 423.

The functions of the SoSCL decoding module 421, the modified SCL decoding module 422, and the modified SoSCL decoding module 423 may be executed by the processor 410. Accordingly, operations that are described in the disclosure to be performed by the SoSCL decoding module 421, the modified SCL decoding module 422, and the modified SoSCL decoding module 423 may be executed by the processor 410 in practice.

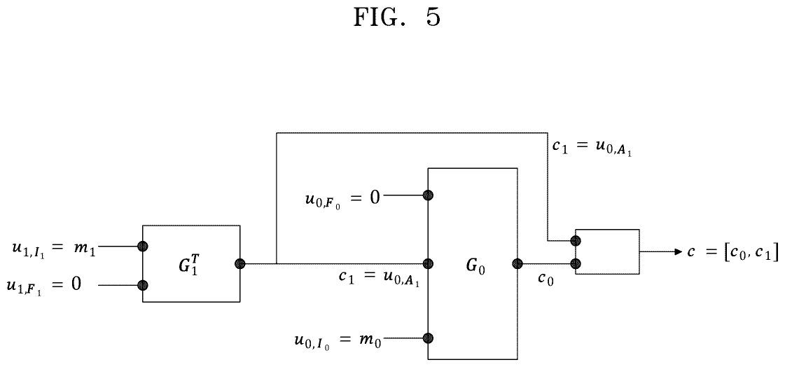

FIG. 5 is a view for describing encoding of single-layer extended deep polar codes according to an embodiment.

The encoding of single-layer extended deep polar codes may include a structure of a pre-transformation layer 1 and a polar transformation layer 0. A pre-transformation module may perform encoding of layer 1, and a polar transformation module may perform encoding of layer 0.

The pre-transformation module sets an input vector u₁ including an information message m₁ of size K₁ and one or more frozen bits. The input vector u₁ may be expressed by Equation 9 below.

u₁=[_{1,I}_{₁},u_{1,F}_{₁}] [Equation 9]

The pre-transformation module performs pre-transformation on the input vector u₁ to generate a codeword c₁ of layer 1. The codeword c₁ may be expressed by Equation 10.

$${c}_{{1}^{=}} [ {u}_{1 , {I}_{1}} , {u}_{1 , {F}_{1}} ] \cdot {G}_{1}^{T} ∈ {\{ 0 , 1 \}}^{{N}_{1}} \qquad [ Equation 10 ]$$

where {0,1}^{N}^{₁} is a set whose elements are binary numbers from 0 to 2^{N}^{₁}−1. I₁ is an information index set of the input vector u₁. F₁ is a frozen index set of the input vector u₁. G₁ is a polar transformation matrix of length N₁. That is, a pre-transformation matrix GIT applied to the input vector u₁ is the transpose of the polar transformation matrix.

In layer 1, the information index set I₁ and the frozen index set F₁ are disjoined from each other and together span the full code length. This means that Equation 11 is satisfied.

I₁∩F₁=Ø and I₁∪F₁=[N₁] [Equation 11]

In layer 1, an information message m₁∈{0,1}^{K}^{₁} is mapped to information bit positions indexed by the information index set I₁. This mapping is expressed as a vector u_{1,I1} of Equation 9. One or more frozen bits are mapped to the remaining positions, and this mapping is expressed as a vector u_{1,F1} of Equation 9.

The pre-transformation module may assign the information message m₁ and the one or more frozen bits to the input vector u₁ in the order of reliability. Accordingly, the information index set I₁ may index high-reliability channels.

The polar transformation module sets an input vector u₀ including the codeword c₁ of layer 1, the information message m₀ of size K₀, and the one or more frozen bits. The input vector u₀ may be expressed as Equation 12 below.

u₀=[u_{0,I}_{₀},u_{0,A}_{₁},u_{0,F}_{₀}] [Equation 12]

The polar transformation module performs polar transformation on the input vector u₀ to generate a codeword c₀ of layer 0. The codeword c₀ may be expressed by Equation 13.

C₀=[u_{0,I}_{⁰},u_{0,A}_{₁},u_{0,F}_{₀}]·G₀∈{0,1}^{N}^{₀} [Equation 13]
where {0,1}^{N}^{₀} is a set whose elements are binary numbers from 0 to 2^{N}^{₀}−1. I₀ is an information index set of the input vector u₀. A₁ refers to a set whose elements are positions of the codeword c₁ in the input vector u₀ (hereinafter, referred to as a connection index set). F₀ is a frozen index set of the input vector u₀. G₀ is a polar transformation matrix of length N₀.

In layer 0, the information index set I₀, the connection index set A₁, and the frozen index set F₁ are mutually exclusive and collectively exhaustive. This means that Equation 14 is satisfied.

I₀∩A₁=I₀∩F₀=A₁∩F₀=Ø and I₀∪A₁∪F₀=[N₀] [Equation 14]

In layer 0, an information message m₀{0,1}^{K}^{₀} is mapped to information bit positions indexed by the information index set I₀. This mapping is expressed as a vector u_{0,I0} of Equation 12. The codeword c₁ of layer 1 is mapped to positions indexed by the connection index set A₁, and this mapping is expressed as a vector u_{0,A1} of Equation 12. A codeword c₁=u_{0,A1} is shared between the layers 0 and 1 and is referred to as a connection bit. The one or more frozen bits are mapped to positions indexed by the frozen index set F₀, and this mapping is expressed as a vector u_{0,F0} of Equation 12.

The polar transformation module may assign the information message m₀, the codeword c₁, and the one or more frozen bits to the input vector u₀ in the order from highest to lowest channel reliability. Accordingly, the information index set I₀ may index channels with highest reliability, the connection index set A₁ may index channels with next highest reliability, and the frozen index set F₀ may index the remaining channels.

The combination module generates an extended codeword c by combining the codeword c₀ of layer 0 with the codeword c₁ of layer 1. The combination module may generate the extended codeword c by concatenating the codeword c₀ with the codeword c₁. The extended codeword c may be expressed by Equation 15.

c=[c₀,c₁]={0,1}^{N}^{₀}^{+N}^{₁} [Equation 15]

A code rate of the extended codeword c may be expressed as Equation 16 below.

$$R = \frac{{K}_{0} + {K}_{1}}{{N}_{0} + {N}_{1}} = \frac{K}{M} \qquad [ Equation 16 ]$$

Because a code block length of the extended codeword c is N₀+N₁, the code block length may not be limited to a power of 2. By appropriately designing N₀ and N₁, the extended codeword c may have various code block lengths that are not limited to powers of 2.

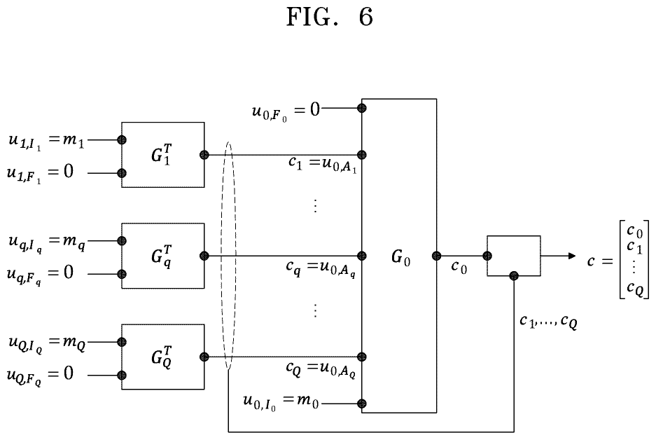

FIG. 6 is a view for describing encoding of multi-layer extended deep polar codes according to an embodiment.

The encoding of multi-layer extended deep polar codes may include a structure of pre-transformation layers 1-Q and a polar transformation layer 0. A processor may split an input message m into Q+1 subvectors m₀, . . . , and m_{Q}. The pre-transformation module may perform encoding of layers 1 through Q for the subvectors m₁, . . . , and m_{Q}, and the polar transformation module may perform encoding of layer 0 for the subvector m₀.

With respect to 1≤q≤Q, encoding of layer q will be described. The pre-transformation module generates an input vector u_{q} by mapping a subvector m_{q} to positions indexed by an information index set I_{q} and mapping the one or more frozen bits to positions indexed by a frozen index set F_{q}. The input vector u_{q} may be expressed by Equation 17 below.

u_{q}=[u_{q,I}_{₀},u_{q,F}_{₀}] [Equation 17]

The pre-transformation module performs pre-transformation on the input vector u_{q} to generate a codeword c_{q} of layer q. The codeword c_{q} may be expressed by Equation 18.

$${c}_{{q}^{=}} [ {u}_{q , {I}_{q}} , {u}_{q , {F}_{q}} ] \cdot {G}_{q}^{T} ∈ {\{ 0 , 1 \}}^{{N}_{q}} \qquad [ Equation 18 ]$$

where G_{q} is a polar transformation matrix of length N_{q}. That is, a pre-transformation matrix G_{q}^{T} applied to the input vector u_{q} is the transpose of the polar transformation matrix.

The polar transformation module generates the input vector u₀ by mapping the subvector m₀ to locations indexed by the information index set I₀, mapping the codeword c_{q} of layer q to locations indexed by a connection index set A_{q}, for 1≤q≤Q, and mapping the one or more frozen bits to locations indexed by the frozen index set F₀. The input vector u₀ may be expressed by Equation 19 below.

u₀=[u_{0,I}_{₀},u_{0,A}_{₁}, . . . ,u_{0,A}_{_{Q}},u_{0,F}_{₀}] [Equation 19]

The polar transformation module may assign the information message m₀, the codewords c₁ through c₀, and the one or more frozen bits to the input vector u₀ in the order from highest to lowest channel reliability. Accordingly, the information index set I₀ may index channels with highest reliability, the connection index sets A₁ through A_{Q} may index channels with next highest reliability, and the frozen index set F₀ may index the remaining channels.

The polar transformation module performs polar transformation on the input vector u₀ to generate the codeword c₀ of layer 0. The codeword c₀ may be expressed by Equation 20.

c₀[u_{0,I}_{₀},u_{0,A}_{₁}, . . . ,u_{0,A}_{_{Q}},u_{0,F}_{₀}]·G₀∈{0,1}^{N}^{₀} [Equation 20]
where G₀ is a polar transformation matrix of length N₀.

The combination module generates an extended codeword c by combining the codeword c₀ of layer 0 with the codewords c₁, . . . , and c₀ of layers 1 through Q. The combination module may generate the extended codeword c by concatenating the codeword c₀ with the codewords c₁, . . . , and c₀. The extended codeword c may be expressed by Equation 21.

c=[c₀,c₁, . . . ,c_{Q}]={0,1}^{N}^{₀}^{+N}^{₁}^{+ . . . +N}^{_{Q}} [Equation 21]

N₀+N₁+ . . . +N_{Q}=M, and, when a length of the input message m is K, the code rate of the extended codeword c is K/M. In K/M, M<2N₀, and K<N₀.

In multi-layer deep polar codes, for 1≤q≤Q, a size of pre-transformation of layer q may be determined based on an extension size M-N₀.

$$M - {N}_{0} = {\sum }_{q = 0}^{{log}_{2} {N}_{0} - 1} {l}_{q} {2}^{q} , where {l}_{q} ∈ \{ 0 , 1 \} \qquad [ Equation 22 ]$$

When the extension size M−N₀ is expressed by Equation 22, the number Q of pre-transformations and a size N_{q} of the pre-transformation of layer q may be expressed by Equations 23 and 24, respectively. Accordingly, a systematic design of multi-layer deep polar codes may be performed.

$$Q = {\sum }_{q = 0}^{{log}_{2} {N}_{0} - 1} {l}_{q} \qquad [ Equation 23 ]$$

$${N}_{q} = {2}^{q} \qquad [ Equation 24 ]$$

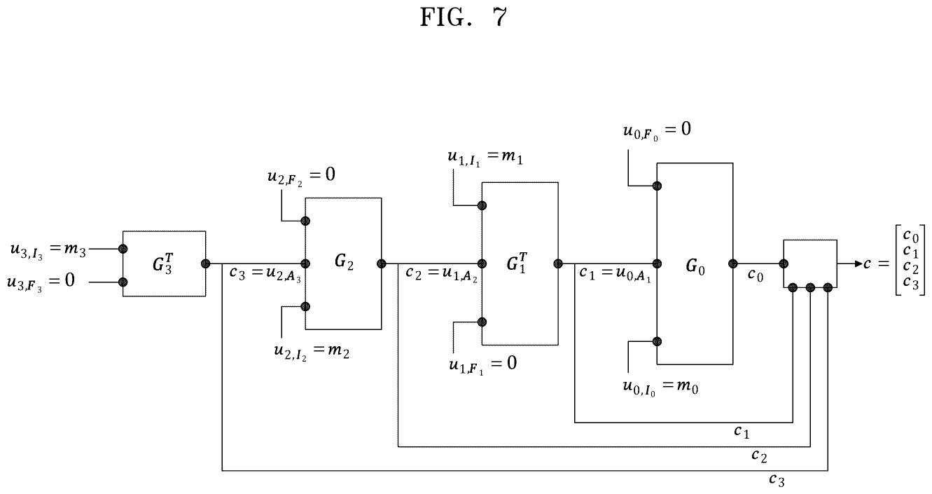

FIG. 7 is a view for describing encoding of multi-layer extended deep polar codes according to an embodiment.

When pre-transformations are performed in parallel in the embodiment of FIG. 6, pre-transformations may be performed in series in the embodiment of FIG. 7. FIG. 7 illustrates an embodiment of performing three pre-transformations, but the number of pre-transformations is not limited thereto.

In layer 3, the pre-transformation module generates an input vector u₃ by mapping information bits m₃ to locations indexed by an information index set I₃ and mapping one or more frozen bits to the remaining locations. The pre-transformation module performs pre-transformation on the input vector u₃ to generate a codeword c₃ of layer 3. The codeword c₃ may be expressed by Equation 25.

$${c}_{3} = [ {u}_{3 , {I}_{3}} , {u}_{3 , {F}_{3}} ] \cdot {G}_{3}^{T} ∈ {\{ 0 , 1 \}}^{{N}_{3}} \qquad [ Equation 25 ]$$

where G₃ is a polar transformation matrix of length N₃.

In layer 2, the pre-transformation module generates an input vector u₂ by mapping information bits m₂ to locations indexed by an information index set I₂, mapping the codeword cs to locations indexed by a connection index set A₃, and mapping one or more frozen bits to the remaining locations. The pre-transformation module performs pre-transformation on the input vector u₂ to generate a codeword c₂ of layer 2. The codeword c₂ may be expressed by Equation 26.

c₂=[u_{2,I}_{₂},u_{2,A}_{₃},u_{2,F}_{₂}]·G₂={0,1}^{N}^{₂} [Equation 26]
where G₂ is a polar transformation matrix of length N₂.

In layer 1, the pre-transformation module generates an input vector u₁ by mapping information bits m₁ to locations indexed by an information index set I₁, mapping the codeword c₂ to locations indexed by a connection index set A₂, and mapping one or more frozen bits to the remaining locations. The pre-transformation module performs pre-transformation on the input vector u₁ to generate a codeword c₁ of layer 1. The codeword c₁ may be expressed by Equation 27.

$${c}_{1} = [ {u}_{1 , {I}_{1}} , {u}_{1 , {A}_{2}} , {u}_{1 , {F}_{1}} ] \cdot {G}_{1}^{T} ∈ {\{ 0 , 1 \}}^{{N}_{1}} \qquad [ Equation 27 ]$$

where G₁ is a polar transformation matrix of length N₁.

In layer 0, the polar transformation module generates an input vector u₀ by mapping the subvector m₀ to locations indexed by the information index set I₀, mapping the codeword c₁ of layer 1 to locations indexed by a connection index set A₁, and mapping the one or more frozen bits to locations indexed by the frozen index set F₀. The polar transformation module performs polar transformation on the input vector u₀ to generate the codeword c₀ of layer 0. The codeword c₀ may be expressed by Equation 28.

c₀=[u_{0,I}_{₀},u_{0,A}_{₁},u_{0,F}_{₀}]·G₀={0,1}^{N}^{₀} [Equation 28]
where G₀ is a polar transformation matrix of length N₀.

The combination module generates an extended codeword c by combining the codewords c₀ through c₃ of layers 0 through 3 with each other. The combination module may generate the extended codeword c by concatenating the codeword c₀ with the codewords C₁, . . . , and c₀. The extended codeword c may be expressed by Equation 29.

c=[c₀,c₁,c₂,c₃]∈{0,1}^{N}^{₀}^{+N}^{₁}^{+N}^{₂}^{+N}^{₃} [Equation 29]

N₀+N₁+N₂+N₃=M, and, when a length of the information bits m₀ through m₃ is K, the code rate of the extended codeword c is K/M.

The polar transform module performs polar transformation by using a polar transformation matrix in layer 0. The pre-transformation module performs pre-transformation by using the transpose of the polar transformation matrix in layers 1 and 3, and performs pre-transformation by using the polar transformation matrix in layer 2. Accordingly, pre-transformation and polar transformation are performed in a form in which a polar transformation matrix and the transpose of the polar transformation matrix are used alternately. Alternating the polar transformation matrix and the transpose of the polar transformation matrix enables fast polar transformation, and may improve a weight distribution of a code.

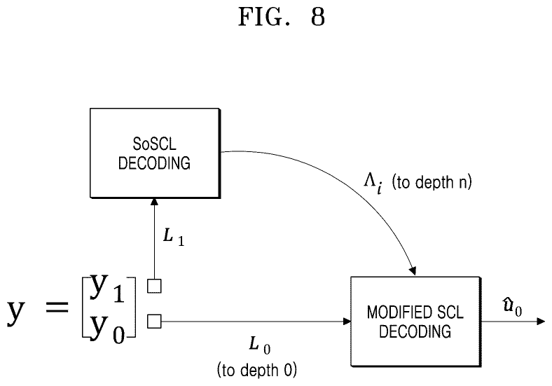

FIG. 8 is a view for describing decoding of single-layer extended deep polar codes according to an embodiment.

Decoding of the codeword c encoded according to the embodiment of FIG. 5 will be described with reference to FIGS. 5 and 8.

A modulated codeword of the codeword c₀ of layer 0 is referred to as x₀, and a modulated codeword of the codeword c₁ of layer 1 is referred to as x₁. A signal vector y received from a channel includes received signals y₀ and y₁, which are noisy versions of the modulated codeword x₀ and the modulated codeword x₁, respectively.

An SoSCL decoding module may perform SCL decoding on the received signal y₁, and a modified SCL decoding module may perform modified SCL decoding on the received signal y₀. The SoSCL decoding module may calculate a soft output for the received signal y₁, and the modified SCL decoding module may perform decoding via a path metric update based on the soft output.

The SoSCL decoding module calculates an LLR vector L₁ of the received signal y₁. The LLR vector L₁ may be expressed by Equation 30.

$${L}_{1} = \frac{2 {y}_{1}}{{σ}^{2}} \qquad [ Equation 30 ]$$

where σ is a standard deviation of channel noise.

The SoSCL decoding module estimates the codeword c₁ of layer 1. The SoSCL decoding module performs SoSCL decoding based on the LLR vector L₁. In addition, the SoSCL decoding module estimates soft information for the codeword c₁ of layer 1, i.e., for connection bits u_{0,A1}. The SoSCL decoding module may estimate the soft information by calculating a log-likelihood ratio (LLR) for the connection bits u_{0,A1} by using the received signal y₁. An LLR ∧ᵢ⁽¹⁾ for an i-th connection bit may be expressed by Equation 31. The LLR may correspond to a posterior LLR for the connection bits u_{0,A1}.

$${Λ}_{i}^{( 1 )} = log \frac{P ( {c}_{1 , i} = 0 \vert {y}_{1} )}{P ( {c}_{1 , i} = 1 \vert {y}_{1} )} = log \frac{P ( {x}_{1 , i} = + 1 \vert {y}_{1} )}{P ( {x}_{1 , i} = - 1 \vert {y}_{1} )} \qquad [ Equation 31 ]$$

where c_{1,i} represents an i-th coded bit, and x_{1,i} represents a modulated symbol corresponding to c_{1,i}.

A soft information vector ∧ may be expressed by Equation 32.

∧=[∧₀, . . . ,∧_{N}_{₀}₋₁] [Equation 32]
where ∧_{A1,i}=∧ᵢ⁽¹⁾, and the remaining elements of ∧ are ∧ᵢ=0. A_{1,i} represents an i-th element of the connection index set A₁.

A modified SCL decoding module calculates an LLR vector L₀ of the received signal y₀. The LLR vector L₀ may be expressed by Equation 33.

$${L}_{0} = \frac{2 {y}_{0}}{{σ}^{2}} \qquad [ Equation 33 ]$$

The modified SCL decoding module performs modified SCL decoding based on the LLR vector L₀ and the soft information vector ∧. Decoding by the modified SCL decoding module by using a modified LLR [symbol] may be expressed by Equation 34.

$$\text{?} = \{ \begin{matrix}{Λ}_{i} + {L}_{n , i} , & if i ∈ {A}_{i , {I}_{1}} , \\ {L}_{n , i} , & otherwise ,\end{matrix} \qquad [ Equation 34 ]$$

where L_{n,i} is the LLR of an i-th bit of an n-th depth, and A_{1,I1}={aᵢ:i∈I₁} represents indices of the connection index set A₁ corresponding to information bits.

By using the modified LLR [symbol] , a path metric PMᵢ[l] of an l-th decoding path may be updated as in Equation 35. This shows that soft information about the connection bits u_{0,A1} is reflected in a path extension process.

PMᵢ[l]=PMᵢ₋₁[l]+log(1+ [symbol] [Equation 35]
where PMᵢ₋₁[l] is an accumulated path metric up to an i−1th bit of an l-th path, and ûᵢ[l] is an estimate of an i-th bit of the l-th path.

A typical SCL decoder processes frozen bits following a current bit in a uniformly random manner. As a result, when a first connection bit û_{A}_{_{1,1}} is decoded, a decoder assumes all subsequent connection bits

$${\hat{u}}_{{A}_{1 , 1}^{c}}$$

to be information bits. In the disclosure, the soft information vector ∧ encodes partial reliability knowledge by including subsequent frozen bits indexed by a connection index set A_{1,F1} corresponding to the frozen bits. Accordingly, the reliability of decoding of the first connection bit û_{A}_{_{1,1}} may be improved.

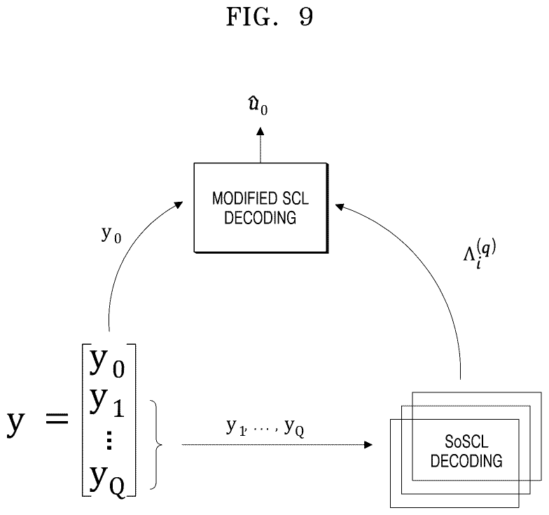

FIG. 9 is a view for describing decoding of multi-layer extended deep polar codes according to an embodiment.

Decoding of the codeword c encoded according to the embodiment of FIG. 6 will be described with reference to FIGS. 6 and 9.

A modulated codeword of the codeword c₀ of layer 0 is referred to as x₀, and, for 1≤q≤Q, a modulated codeword of the codeword c_{q} of layer q is referred to as x_{q}. A signal vector y received from a channel includes received signals y₀ through y_{Q}, which are noisy versions of modulated codewords x₀ through x_{Q}, respectively.

The SoSCL decoding module may estimate Q codewords c₁ through c₀ of layers 1 through Q by performing SoSCL decoding in parallel.

With respect to 1≤q≤Q, decoding of a received signal y_{q} will be described. The SoSCL decoding module estimates a codeword c_{q} of layer q from the received signal y_{q}. In addition, the SoSCL decoding module calculates a soft output for the codeword c_{q} of layer q as in Equation 36.

$${Λ}_{i}^{( q )} = log \frac{P ( {c}_{q , i} = 0 \vert {y}_{q} )}{P ( {c}_{q , i} = 1 \vert {y}_{q} )} = log \frac{P ( {x}_{q , i} = + 1 \vert {y}_{q} )}{P ( {x}_{q , i} = - 1 \vert {y}_{q} )} \qquad [ Equation 36 ]$$

where c_{q,i} is an i-th coded bit of the codeword c_{q} of layer q, and x_{q,i} is a modulated symbol corresponding to c_{q,i}.

A soft information vector ∧ may be expressed by Equation 37.

∧=[∧₀, . . . ,∧_{N}_{₀}₋₁] [Equation 37]
where ∧_{Aq,i}=∧ᵢ^{(q)}, and the remaining elements of ∧ are ∧ᵢ=0. A_{q,i} represents an i-th element of the connection index set A_{q}.

A modified SCL decoding module may estimate the codeword c₀ of layer 0 by performing modified SCL decoding. Decoding by the modified SCL decoding module by using a modified LLR [symbol] based on the soft information vector ∧ may be expressed by Equation 38.

$$\text{?} = \{ \begin{matrix}{Λ}_{i} + {L}_{n , i} , & if i ∈ {A}_{q , {I}_{q}} , \\ {L}_{n , i} , & otherwise ,\end{matrix} \qquad [ Equation 38 ]$$

where L_{n,i} is the LLR of an i-th bit of an n-th depth, and A_{q,Iq} represents indices of the connection index set A_{q} corresponding to information bits.

By using the modified LLR [symbol] , a path metric PMᵢ[l] of an l-th decoding path may be updated as in Equation 35.

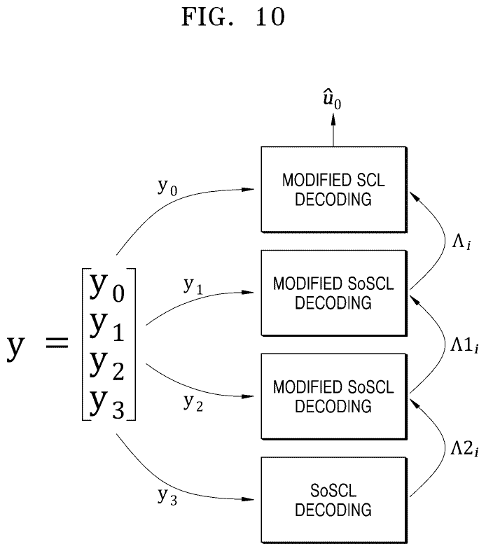

FIG. 10 is a view for describing decoding of multi-layer extended deep polar codes according to an embodiment.

Decoding of the codeword c encoded according to the embodiment of FIG. 7 will be described with reference to FIGS. 7 and 10.

Modulated codewords of codewords c₀ through c₃ of layers 0 through 3 are referred to as x₀ through x₃, respectively. A signal vector y received from a channel includes received signals y₀ through y₃, which are noisy versions of the modulated codewords x₀ through x₃, respectively.

The SoSCL decoding module estimates a codeword c₃ of layer 3 from the received signal y₃ by performing SCL decoding. In addition, the SoSCL decoding module calculates a soft output for the codeword c₃ of layer 3 as in Equation 39.

$${Λ}_{i}^{( 3 )} = log \frac{P ( {c}_{3 , i} = 0 \vert {y}_{3} )}{P ( {c}_{3 , i} = 1 \vert {y}_{3} )} = log \frac{P ( {x}_{3 , i} = + 1 \vert {y}_{3} )}{P ( {x}_{3 , i} = - 1 \vert {y}_{3} )} \qquad [ Equation 39 ]$$

where c_{3,i} represents an i-th coded bit of the codeword c₃ of layer 3, and x_{3,i} represents a modulated symbol corresponding to c_{3,i}.

A soft information vector ∧2 may be expressed by Equation 40.

∧2=[∧2₀, . . . ,∧2_{N}_{₂}₋₁] [Equation 40]
where ∧2_{A3,i}=∧ᵢ⁽³⁾, and the remaining elements of ∧2 are ∧2ᵢ=0. A_{3,i} represents an i-th element of the connection index set A₃.

The modified SoSCL decoding module performs modified SCL decoding by using the received signal y₂ and the soft information vector ∧2. A modified LLR [symbol] used in the modified SCL decoding may be expressed by Equation 41.

$$\text{?} = \{ \begin{matrix}{Λ2}_{i} + {L}_{n , i} , & if i ∈ {A}_{3 , {I}_{3}} , \\ {L}_{n , i} , & otherwise ,\end{matrix} \qquad [ Equation 41 ]$$

where L_{n,i} is the LLR of an i-th bit of an n-th depth, and A_{3,I3} represents indices of the connection index set A₃ corresponding to information bits.

By using the modified LLR [symbol] , a path metric PMᵢ[l] of an l-th decoding path may be updated as in Equation 35.

In addition, the modified SoSCL decoding module calculates a soft output for the codeword c₂ of layer 2 as in Equation 42.

$${Λ}_{i}^{( 2 )} = log \frac{P ( {c}_{2 , i} = 0 \vert {y}_{2} )}{P ( {c}_{2 , i} = 1 \vert {y}_{2} )} = log \frac{P ( {x}_{2 , i} = + 1 \vert {y}_{2} )}{P ( {x}_{2 , i} = - 1 \vert {y}_{2} )} \qquad [ Equation 42 ]$$

where c_{2,i} represents an i-th coded bit of the codeword c₂ of layer 2, and x_{2,i} represents a modulated symbol corresponding to c_{2,i}.

A soft information vector ∧1 may be expressed by Equation 43.

∧1=[∧1₀, . . . ,∧1_{N}_{₁}₋₁] [Equation 43]
where ∧_{A2,i}=∧ᵢ⁽²⁾, and the remaining elements of ∧1 are ∧1ᵢ=0. A_{2,i} represents an i-th element of the connection index set A₂.

In a similar method to the received signal y₂, the modified SCL decoding module may perform modified SCL decoding by using the received signal y₁ and the soft information vector ∧1. In addition, the modified SoSCL decoding module may generate a soft output vector ∧ for the codeword c₁ of layer 1. An operation, performed by the modified SoSCL decoding module, of generating the soft output vector ∧ may be expressed as in Equations 31 and 32.

As described above, the modified SoSCL decoding module includes a function of the SoSCL decoding module to generate a soft output and a function of the modified SCL decoding module to update a path metric in which soft information of connection bits has been reflected.

The modified SCL decoding module decodes the codeword c₀ of layer 0 by using the received signal y₀ and the soft information vector ∧. Decoding by the modified SCL decoding module by using a modified LLR [symbol] may be expressed by Equation 44.

$$\text{?} = \{ \begin{matrix}{Λ}_{i} + {L}_{n , i} , & if i ∈ {A}_{1 , {I}_{1}} , \\ {L}_{n , i} , & otherwise ,\end{matrix} \qquad [ Equation 44 ]$$

where A_{1,I1} represents indices of the connection index set A₁ corresponding to information bits.

By using the modified LLR [symbol] , a path metric PMᵢ[l] of an l-th decoding path may be updated as in Equation 35.

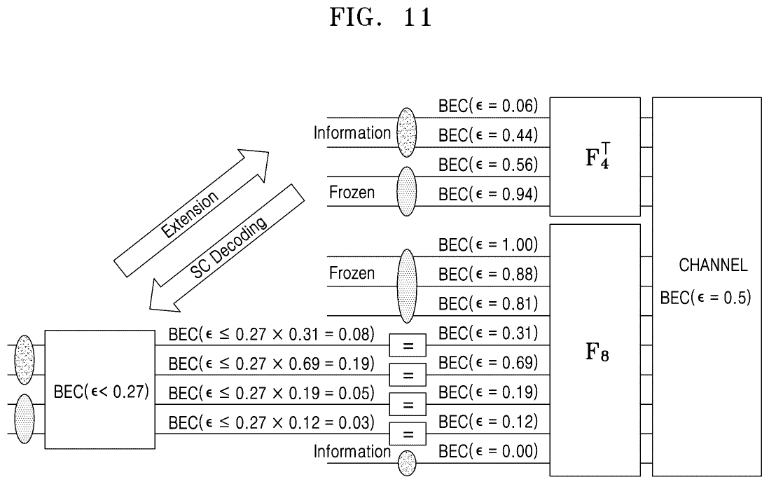

FIG. 11 is a view illustrating an example of extended deep polar codes according to an embodiment.

In the example, a length of a combined codeword is M=12, a length of information bits is K=3, a length of a codeword of layer 0 is N₀=8, and a length of a codeword of layer 1 is N₁=4. A binary erasure channel (BEC) was used, and an erasure probability of the BEC is ε=0.5.

Because the codeword c₁ of layer 1, which is an extended part, is transmitted via the BEC having the erasure probability ε=0.5 and includes polar codewords, polarized bit channels are BECs having an erasure probability ε∈{0.06, 0.44, 0.56, 0.94}. It is assume that information bits are transmitted on two best polarized channels among the bit channels. A BLER of the two channels has an upper limit as in Equation 45.

$$BLER < 1 - ( 1 - 0.44 ) ( 1 - 0.06 ) - \frac{1}{2} \times 0.44 \times ( 1 - 0.06 ) = \frac{27}{100} \qquad [ Equation 45 ]$$

After the extended part is decoded, a corresponding pre-transformed part may be considered to have been transmitted via a BEC having an erasure probability less than 0.27. This upper limit is combined with the original polarized channels via equality constraints, resulting in upgraded BEC having an erasure probability of 0.27×εᵢ. εᵢ is an erasure probability of an i-th polarized channel. Accordingly, in the absence of extension, information may be transmitted via bit channels having ε∈{0.19, 0.12, 0.00}, but, with extension, information may be transmitted via bit channels having ε∈{0.08, 0.19, 0.00}.

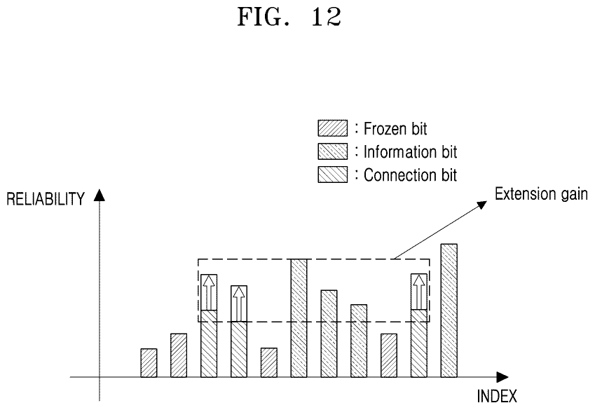

FIG. 12 is a graph for explaining an improvement in reliability of extended deep polar codes according to an embodiment.

In the disclosure, an extended codeword is generated by concatenating connection bits to a polar codeword, the extended part is first decoded, and then the polar codeword is decoded by updating a path metric by using a modified LLR in which soft information of the extended part has been reflected. Accordingly, reliability of connection bits may be improved by reflecting soft information about the connection bits in a path extension process of SCL decoding. In addition, by selectively performing a path metric update using a modified LLR for the connection bits, the reliability of the connection bits may be improved without affecting the reliability of information bits and frozen bits.

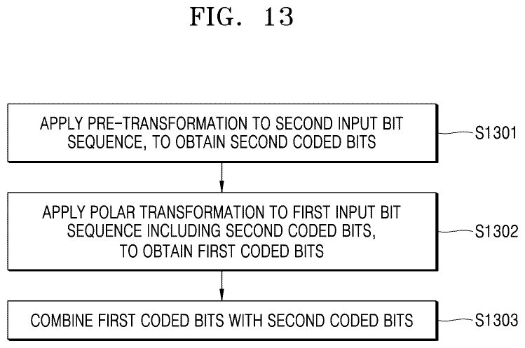

FIG. 13 is a flowchart of an encoding operation according to an embodiment.

In operation S1301, a pre-transformation module applies pre-transformation to a second input bit sequence to obtain second coded bits.

The pre-transformation module may generate a second input bit sequence including one or more second information bits and one or more second frozen bits. In the embodiment of FIG. 5, the pre-transformation module generates a second input bit sequence u₁ including one or more second information bits u_{1,I1} and one or more second frozen bits u_{1,F1}.

The pre-transformation module may obtain second coded bits by applying a pre-transformation matrix to the second input bit sequence. The pre-transformation matrix may be the transpose of a polar transformation matrix. In the embodiment of FIG. 5, the pre-transformation module applies a pre-transformation matrix G₁^{T} to the second input bit sequence u₁ to obtain second coded bits c₁.

In operation S1302, a polar transformation module applies polar transformation to a first input bit sequence including the second coded bits, in order to obtain first coded bits.

The polar transformation module may generate a first input bit sequence including one or more first information bits, one or more first frozen bits, and the second coded bits. In the embodiment of FIG. 5, the polar transformation module generates a first input bit sequence u₀ including one or more first information bits u_{0,I0}, one or more first frozen bits u_{0,F0}, and the second coded bits c₁.

The polar transformation module may assign the one or more first information bits, the second coded bits, and the one or more first frozen bits to the first input bit sequence in the order from highest to lowest channel reliability. In the embodiment of FIG. 5, the polar transformation module generates an information index set I₀ to include K₀ indices having high channel reliability, generates a connection index set A₁ to include N₁ indices having next highest channel reliability, and generates a frozen index set F₀ to include the remaining indices.

In operation S1303, a combination module combines the first coded bits with the second coded bits.

The combination module may combine the first coded bits with the second coded bits such that combined coded bits have a code length that is not a power of 2. A code rate of the combined coded bits may be a ratio of a sum of a length of an information bit of the first coded bits and a length of an information bit of the second coded bits to a sum of a code length of the first coded bits and a code length of the second coded bits. In the embodiment of FIG. 5, the code rate of the combined coded bits is K/M.

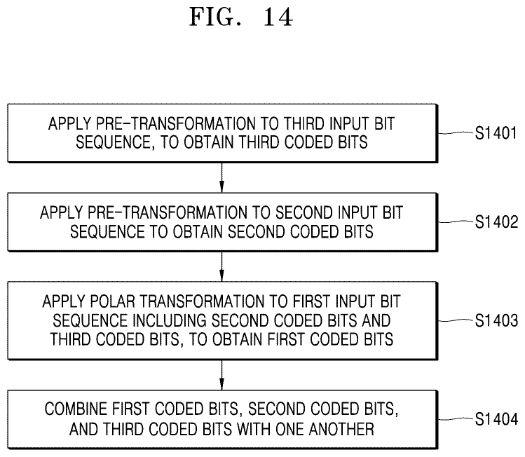

FIG. 14 is a flowchart of an encoding operation according to an embodiment.

In operation S1401, a pre-transformation module applies pre-transformation to a third input bit sequence to obtain third coded bits.

The pre-transformation module may generate a third input bit sequence including one or more third information bits and one or more third frozen bits.

In operation S1402, the pre-transformation module applies pre-transformation to a second input bit sequence to obtain second coded bits.

The pre-transformation module may generate a second input bit sequence including one or more second information bits and one or more second frozen bits.

The pre-transformation module may generate a plurality of input bit sequences from operations S1401 and S1402. In the embodiment of FIG. 6, the pre-transformation module generates Q input bit sequences u_{q} including one or more information bits u_{q,Iq} and one or more frozen bits u_{q,Fq}.

The pre-transformation module may obtain coded bits by applying pre-transformation matrices to the plurality of input bit sequences. The pre-transformation matrices may be the transposes of polar transformation matrices. In the embodiment of FIG. 6, the pre-transformation module applies a pre-transformation matrix G_{q}^{T} to an input bit sequence u_{q} to obtain coded bits c_{q}.

In operation S1403, a polar transformation module applies polar transformation to a first input bit sequence including the second coded bits and the third coded bits, in order to obtain first coded bits.

The polar transformation module may generate a first input bit sequence including one or more first information bits, one or more first frozen bits, the second coded bits, and the third coded bits. In the embodiment of FIG. 6, the polar transformation module generates a first input bit sequence u₀ including one or more first information bits u_{0,I0}, one or more first frozen bits u_{0,F0}, and coded bits c₁ through c_{Q}.

The polar transformation module may assign the one or more first information bits, the second coded bits, the third coded bits, and the one or more first frozen bits to the first input bit sequence in the order from highest to lowest channel reliability. In the embodiment of FIG. 6, the polar transformation module generates an information index set I₀ to include K₀ indices having high channel reliability, generates connection index sets A₁ through A_{Q} to include N₁+ . . . +N_{Q} indices having next high channel reliability, and generates a frozen index set F₀ to include the remaining indices.

In operation S1404, a combination module combines the first coded bits, the second coded bits, and the third coded bits with one another.

The combination module may combine the first coded bits, the second coded bits, and the third coded bits with one another such that combined coded bits have a code length that is not a power of 2. In the embodiment of FIG. 6, the code rate of the combined coded bits is K/M.

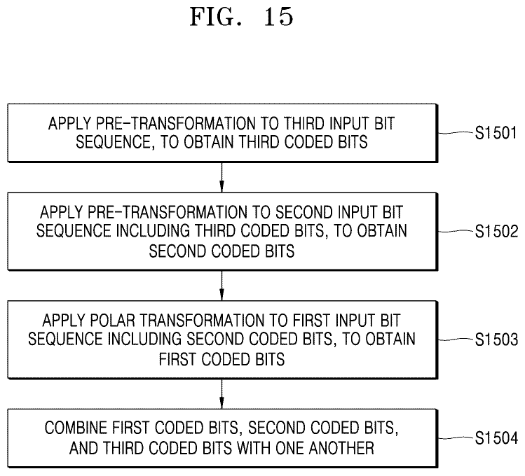

FIG. 15 is a flowchart of an encoding operation according to an embodiment.

In operation S1501, a pre-transformation module applies pre-transformation to a third input bit sequence to obtain third coded bits.

The pre-transformation module may generate a third input bit sequence including one or more third information bits and one or more third frozen bits.

In operation S1502, the pre-transformation module applies pre-transformation to a second input bit sequence including the third coded bits, in order to obtain second coded bits.

The pre-transformation module may generate a second input bit sequence including one or more second information bits, the third coded bits, and one or more second frozen bits.

The pre-transformation module may assign the one or more second information bits, the third coded bits, and the one or more second frozen bits to the second input bit sequence in the order from highest to lowest channel reliability.

The pre-transformation module may be implemented by extending operation S1502. In the embodiment of FIG. 7, the pre-transformation module applies pre-transformation to an input bit sequence u₂ including coded bits c₃ to obtain coded bits c₃, and applies pre-transformation to an input bit sequence u₁ including coded bits c₂ to obtain coded bits c₁.

In operation S1503, a polar transformation module applies polar transformation to a first input bit sequence including the second coded bits, in order to obtain first coded bits.

The polar transformation module may generate a first input bit sequence including one or more first information bits, one or more first frozen bits, and the second coded bits. In the embodiment of FIG. 7, the polar transformation module generates a first input bit sequence u₀ including one or more first information bits u_{0,I0}, one or more first frozen bits u_{0,F0}, and the second coded bits c₁.

The pre-transformation module and the polar transformation module may alternately apply a polar transformation matrix and the transpose of the polar transformation matrix for each layer. The polar transformation module may generate first coded bits by applying a polar transformation matrix to a first input bit sequence, the pre-transform module may generate second coded bits by applying a pre-transformation matrix, which is a transpose of the polar transformation matrix, to a second input bit sequence, and the pre-transformation module may generate third coded bits by applying a pre-transformation matrix, which is a polar transformation matrix, to a third input bit sequence.

The polar transformation module may assign the one or more first information bits, the second coded bits, and the one or more first frozen bits to the first input bit sequence in the order from highest to lowest channel reliability.

In operation S1504, a combination module combines the first coded bits, the second coded bits, and the third coded bits with one another.

The combination module may combine the first coded bits, the second coded bits, and the third coded bits with one another such that combined coded bits have a code length that is not a power of 2. In the embodiment of FIG. 7, the code rate of the combined coded bits is K/M.

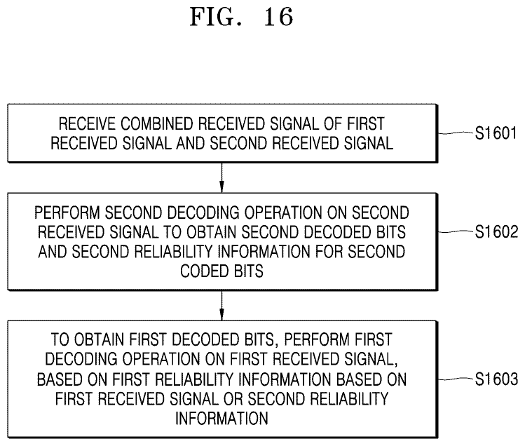

FIG. 16 is a flowchart of a decoding operation according to an embodiment.

FIG. 16 illustrates a decoding operation corresponding to the encoding operation according to the embodiment of FIG. 13.

Referring to FIGS. 13 and 16 together, in operation S1601, an electronic device receives a combined received signal of a first received signal and a second received signal. The combined received signal corresponds to the combined coded bits, the first received signal corresponds to the first coded bits, and the second received signal corresponds to the second coded bits. The first coded bits are generated by applying a polar transformation to a first input bit sequence including the second coded bits. The second coded bits are generated by applying a pre-transformation to a second input bit sequence including one or more information bits and one or more frozen bits.

In operation S1602, the SoSCL decoding module performs a second decoding operation on the second received signal to obtain second decoded bits and second reliability information for the second coded bits.

The second decoding operation may be SCL decoding. The SoSCL decoding module may obtain the second decoded bits by performing SCL decoding on the second received signal. The SoSCL decoding module may generate the second reliability information from a soft output of SCL decoding. The second reliability information may include LLR values of the second coded bits corresponding to the second decoded bits. In the embodiment referring to FIG. 8, the second reliability information is a soft information vector ∧.

In operation S1603, in order to obtain first decoded bits, the modified SCL decoding module performs a first decoding operation on the first received signal, based on first reliability information based on the first received signal or the second reliability information.

The first decoding operation may be a modified SCL decoding operation. The modified SoSCL decoding module may obtain first decoded bits by performing modified SCL decoding on the first received signal.

The modified SCL decoding operation may refer to an SCL decoding operation via a path metric update based on ‘first reliability information and second reliability information’ or ‘first reliability information’. The first reliability information may include LLR values of SCL decoding based on the first received signal. In the embodiment with reference to FIG. 8, the first reliability information is L_{n,i} of Equation 34, and the second reliability information is ∧ᵢ of Equation 34. In the embodiment with reference to FIG. 8, the path metric update is expressed by Equation 35.

The modified SCL decoding module may perform a first decoding operation with respect to elements of a first input bit sequence indexed by a predetermined index set, based on the first reliability information and the second reliability information. In addition, the modified SCL decoding module may perform a first decoding operation with respect to elements of the first input bit sequence not indexed by the predetermined index set, based on the first reliability information. The predetermined index set is a set that includes, as an element, an index of a coded bit corresponding to an information bit among the second coded bits in the first input bit sequence. In the embodiment referring to FIG. 8, the predetermined index set is A_{1,I1}.

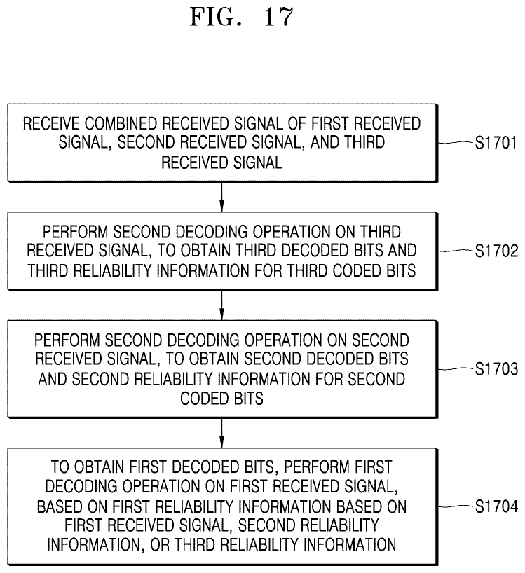

FIG. 17 is a flowchart of a decoding operation according to an embodiment.

FIG. 17 illustrates a decoding operation corresponding to the encoding operation according to the embodiment of FIG. 14.

Referring to FIGS. 14 and 17 together, in operation S1701, an electronic device receives a combined received signal of a first received signal, a second received signal, and a third received signal. The combined received signal corresponds to the combined coded bits, the first received signal corresponds to the first coded bits, the second received signal corresponds to the second coded bits, and the third received signal corresponds to the third coded bits. The first coded bits are generated by applying a polar transformation to a first input bit sequence including the second coded bits and the third coded bits.

In operation S1702, the SoSCL decoding module performs a second decoding operation on the third received signal to obtain third decoded bits and third reliability information for the third coded bits.

In operation S1703, the SoSCL decoding module performs a second decoding operation on the second received signal to obtain second decoded bits and second reliability information for the second coded bits.

The second decoding operation may be SCL decoding. The SoSCL decoding module may obtain the second decoded bits and the third decoded bits by respectively performing SCL decoding operations on the second received signal and the third received signal. The second decoding operations may be performed in parallel.

The second reliability information may include LLR values of the second coded bits corresponding to the second decoded bits. The third reliability information may include LLR values of the third coded bits corresponding to the third decoded bits.

In operation S1704, in order to obtain first decoded bits, the modified SCL decoding module performs a first decoding operation on the first received signal, based on first reliability information based on the first received signal, the second reliability information, or the third reliability information.

The first decoding operation may be a modified SCL decoding operation. The modified SCL decoding module may obtain first decoded bits by performing modified SCL decoding on the first received signal.

The modified SCL decoding operation may refer to an SCL decoding operation via a path metric update based on ‘first reliability information and second reliability information’, ‘first reliability information and third reliability information’, or ‘first reliability information’. The first reliability information may include LLR values of SCL decoding based on the first received signal. In the embodiment referring to FIG. 9, the first reliability information is L_{n,i} of Equation 38, and the second reliability information (or the third reliability information) is ∧ᵢ of Equation 38.

The modified SCL decoding module may perform a first decoding operation with respect to elements of a first input bit sequence indexed by a predetermined index set, based on ‘first reliability information and second reliability information’ or ‘first reliability information and third reliability information’. In addition, the modified SCL decoding module may perform a first decoding operation with respect to elements of the first input bit sequence not indexed by the predetermined index set, based on the ‘first reliability information’. The predetermined index set is a set that includes, as an element, an index of a coded bit corresponding to an information bit among the second coded bits and the third coded bits in the first input bit sequence. In the embodiment referring to FIG. 9, the predetermined index set is A_{q,Iq} for 1≤q≤Q.

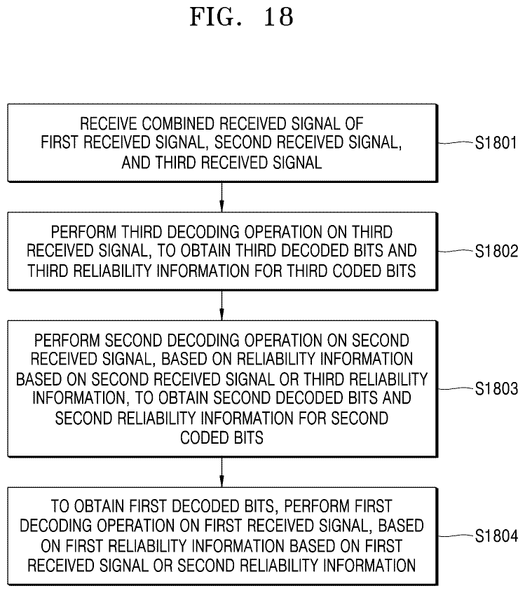

FIG. 18 is a flowchart of a decoding operation according to an embodiment.

FIG. 18 illustrates a decoding operation corresponding to the encoding operation according to the embodiment of FIG. 15.

Referring to FIGS. 15 and 18 together, in operation S1801, an electronic device receives a combined received signal of a first received signal, a second received signal, and a third received signal. The combined received signal corresponds to the combined coded bits, the first received signal corresponds to the first coded bits, the second received signal corresponds to the second coded bits, and the third received signal corresponds to the third coded bits. The first coded bits are generated by applying a polar transformation to a first input bit sequence including the second coded bits. The second coded bits are generated by applying a pre-transformation to a second input bit sequence including the third coded bits. The third coded bits are generated by applying a pre-transformation to a third input bit sequence including one or more information bits and one or more frozen bits.

In operation S1802, the SoSCL decoding module performs a third decoding operation on the third received signal to obtain third decoded bits and third reliability information for the third coded bits.

The third decoding operation may be SCL decoding. The SoSCL decoding module may obtain the third decoded bits by performing SCL decoding on the third received signal. The third reliability information may include LLR values of the third coded bits corresponding to the third decoded bits.

In operation S1803, the modified SoSCL decoding module performs a second decoding operation on the second received signal, based on reliability information based on the second received signal or the third reliability information, in order to obtain second decoded bits and second reliability information for the second coded bits.

The second decoding operation may be modified SoSCL decoding. The modified SoSCL decoding may refer to an operation of SCL decoding through a path metric update based on ‘reliability information based on the second received signal and third reliability information’ or ‘reliability information based on the second received signal’ and an operation of generating the second reliability information for the second coded bits.

The reliability information based on the second received signal may include LLR values of modified SCL decoding of the second received signal. In the embodiment referring to FIG. 9, the reliability information based on the second received signal is L_{n,i} of Equation 41, and the third reliability information is ∧2ᵢ of Equation 41.

In operation S1804, in order to obtain first decoded bits, the modified SCL decoding module performs a first decoding operation on the first received signal, based on first reliability information based on the first received signal or the second reliability information.

The first decoding operation may be a modified SCL decoding operation. The modified SoSCL decoding module may obtain first decoded bits by performing modified SCL decoding on the first received signal. In the embodiment referring to FIG. 9, the first reliability information is L_{n,i} of Equation 44, and the second reliability information is ∧ᵢ of Equation 44.

According to embodiments, coded bits whose code length is not limited to a power of 2 are provided.

According to embodiments, the reliability of bit channels may be improved after polar code extension.

According to embodiments, a coding gain inherent in a pre-transformation layer may be effectively utilized while maintaining structural advantages of a deep polar code.

According to embodiments, an efficient decoding algorithm that integrates soft information of the pre-transformation layer into a primary decoding process is provided. Furthermore, by utilizing SoSCL decoding, an overall decoding performance may be improved with minimal complexity overhead by utilizing future frozen constraints within a successive cancellation (SC) decoding framework, allowing components in each layer to contribute to reliability improvement.

Embodiments of the disclosure can also be embodied as a storage medium including instructions executable by a computer such as a program module executed by the computer. A computer readable medium can be any available medium which can be accessed by the computer and includes all volatile/non-volatile and removable/non-removable media. Computer-readable media may also include computer storage media. The computer storage medium includes all volatile/non-volatile and removable/non-removable media embodied by a certain method or technology for storing information such as computer readable instruction code, a data structure, a program module or other data.

In addition, computer-readable storage media may be provided in the form of non-transitory storage media. The ‘non-transitory storage medium’ is a tangible device and only means that it does not contain a signal (e.g., electromagnetic waves). This term does not distinguish a case in which data is stored semi-permanently in a storage medium from a case in which data is temporarily stored. For example, the ‘non-transitory recording medium’ may include a buffer in which data is temporarily stored.

According to an embodiment, methods according to various disclosed embodiments may be provided by being included in a computer program product. The computer program product, which is a commodity, may be traded between sellers and buyers. Computer program products are distributed in the form of device-readable storage media (e.g., compact disc read only memory (CD-ROM)), or may be distributed (e.g., downloaded or uploaded) through an application store or between two user devices (e.g., smartphones) directly and online. In the case of online distribution, at least a portion of the computer program product (e.g., a downloadable app) may be stored at least temporarily in a device-readable storage medium, such as a memory of a manufacturer's server, a server of an application store, or a relay server, or may be temporarily generated.

While the disclosure has been particularly shown and described with reference to exemplary embodiments thereof, it will be understood that various changes in form and details may be made therein without departing from the spirit and scope of the disclosure. Thus, the above-described embodiments should be considered in descriptive sense only and not for purposes of limitation. For example, each component described as a single type may be implemented in a distributed manner, and similarly, components described as being distributed may be implemented in a combined form.

The scope of the disclosure is indicated by the scope of the claims to be described later rather than the above detailed description, and all changes or modified forms derived from the meaning and scope of the claims and the concept of equivalents thereof should be interpreted as being included in the scope of the disclosure.

What is claimed is:

1. A method for communication, the method comprising:
applying a pre-transformation to a second input bit sequence, to obtain second coded bits;
applying a polar transformation to a first input bit sequence including the second coded bits, to obtain first coded bits; and
combining the first coded bits with the second coded bits.

2. The method of claim 1, wherein the combining includes combining the first coded bits with the second coded bits such that the combined coded bits have a code length that is not a power of 2.

3. The method of claim 1, wherein the applying of the polar transformation to the first input bit sequence includes generating the first input bit sequence including one or more first information bits, one or more first frozen bits, and the second coded bits.

4. The method of claim 3, wherein the generating of the first input bit sequence includes assigning the one or more first information bits, the second coded bits, and the one or more first frozen bits to the first input bit sequence in the order from highest to lowest channel reliability.

5. The method of claim 1, wherein the applying of the pre-transformation to the second input bit sequence includes generating the second input bit sequence including one or more second information bits and one or more second frozen bits.

6. The method of claim 1, further comprising applying a pre-transformation to a third input bit sequence, to obtain third coded bits,
wherein
the applying of the polar transformation to the first input bit sequence includes applying a polar transformation to the first input bit sequence including the second coded bits and the third coded bits, to obtain the first coded bits, and
the combining includes combining the first coded bits, the second coded bits, and the third coded bits.

7. The method of claim 1, further comprising applying a pre-transformation to a third input bit sequence, to obtain third coded bits,
wherein
the applying of the pre-transformation to the second input bit sequence includes applying a pre-transformation to the second input bit sequence including the third coded bits, to obtain the second coded bits, and
the combining includes combining the first coded bits, the second coded bits, and the third coded bits.

8. The method of claim 7, wherein
the applying of the pre-transformation to the second input bit sequence includes applying, to the second input bit sequence, a pre-transformation matrix that is a transpose of a polar transformation matrix, and
the applying of the pre-transformation to the third input bit sequence includes applying, to the third input bit sequence, a pre-transformation matrix that is a polar transformation matrix.

9. The method of claim 1, wherein a code rate of the combined coded bits is a ratio of a sum of a length of an information bit of the first coded bits and a length of an information bit of the second coded bits to a sum of a code length of the first coded bits and a code length of the second coded bits.

10. The method of claim 1, wherein the applying of the pre-transformation to the second input bit sequence includes applying, to the second input bit sequence, a pre-transformation matrix that is a transpose of a polar transformation matrix.

11. An electronic device for communication, the electronic device comprising:
a memory storing instructions; and
a processor configured to execute the instructions,
wherein the processor is configured to execute the instructions to:
apply a pre-transformation to a second input bit sequence, to obtain second coded bits;
apply a polar transformation to a first input bit sequence including the second coded bits, to obtain first coded bits; and
combine the first coded bits with the second coded bits.

12. A method for communication, the method comprising:
receiving a combined received signal of a first received signal and a second received signal, wherein the first received signal corresponds to first coded bits, the second received signal corresponds to second coded bits, and the first coded bits are generated by applying a polar transformation to an input bit sequence including the second coded bits;
performing a second decoding operation on the second received signal, to obtain second decoded bits and second reliability information for the second coded bits; and
to obtain first decoded bits, performing a first decoding operation on the first received signal, based on first reliability information based on the first received signal or the second reliability information.

13. The method of claim 12, wherein
the performing of the first decoding operation on the first received signal comprises:
performing a first decoding operation with respect to elements of the first input bit sequence indexed by a predetermined index set, based on the first reliability information and the second reliability information; and
performing a first decoding operation with respect to elements of the first input bit sequence not indexed by the predetermined index set, based on the first reliability information.

14. The method of claim 13, wherein
the second coded bits are generated by applying a pre-transformation to a second input bit sequence including one or more information bits and one or more frozen bits, and
the predetermined index set is a set that includes, as elements, indices of coded bits corresponding to the one or more information bits among the second coded bits in the first input bit sequence.

15. The method of claim 13, wherein
the performing of the first decoding operation, based on the first reliability information and the second reliability information, comprises performing successive cancellation list (SCL) decoding via a path metric update based on the first reliability information and the second reliability information, and
the performing of the first decoding operation, based on the first reliability information, comprises performing SCL decoding via a path metric update based on the first reliability information.

16. The method of claim 12, wherein the second reliability information includes log-likelihood ratio (LLR) values for the second coded bits.

17. The method of claim 12, wherein the first reliability information includes LLR values of SCL decoding based on the first received signal.

18. The method of claim 12, wherein
the combined received signal corresponds to combined coded bits of the first coded bits and the second coded bits,
the first coded bits are generated by applying a polar transformation to a first input bit sequence including one or more information bits, one or more frozen bits, and the second coded bits, and
the second coded bits are generated by applying a pre-transformation to a second input bit sequence including one or more information bits and one or more frozen bits.

19. The method of claim 12, wherein
the receiving of the combined received signal includes receiving a combined received signal of the first received signal, the second received signal, and a third received signal, wherein the third received signal corresponds to third coded bits, and the first coded bits are generated by applying a polar transformation to an input bit sequence including the second coded bits and the third coded bits,
the method further comprises performing a second decoding operation on the third received signal to obtain third decoded bits and third reliability information for the third coded bits, and
the performing of the first decoding operation further includes performing a first decoding operation on the first received signal, based on first reliability information based on the first received signal, the second reliability information, or the third reliability information.

20. The method of claim 12, wherein
the receiving of the combined received signal includes receiving a combined received signal of the first received signal, the second received signal, and a third received signal, wherein the third received signal corresponds to third coded bits, and the second coded bits are generated by applying a pre-transformation to an input bit sequence including the third coded bits,
the method of claim 12 further comprises performing a third decoding operation on the third received signal, to obtain third decoded bits and third reliability information for the third coded bits, and
the performing of the second decoding operation further includes performing the second decoding operation on the second received signal, based on the third reliability information.
